(19) United States
(12) Patent Application Publication
(10) Pub. No.: US 2026/0208621 A1
(43) Pub. Date: Jul. 23, 2026

(54) BATTERY CONTROL SYSTEM, CONTROL METHOD, AND RECORDING MEDIUM

(71) Applicant: HONDA MOTOR CO., LTD., Tokyo (JP)

(72) Inventors: Kosuke Murata, Tokyo (JP); Takushi Inoue, Tokyo (JP); Shimpei Sawano, Tokyo (JP); Masatoshi Kobayashi, Tokyo (JP); Satoshi Aiyoshizawa, Tokyo (JP); Takayuki Inomata, Tokyo (JP); Toru Nakanishi, Tokyo (JP); Hidetoshi Hasegawa, Tokyo (JP); Kazutaka Yoshimura, Tokyo (JP); Yusuke Takahashi, Tokyo (JP); Toru Kitajima, Tokyo (JP)

(21) Appl. No.: 19/426,770

(22) Filed: Dec. 19, 2025

(30) Foreign Application Priority Data
Jan. 23, 2025 (JP) 2025-009775

(51) Int. Cl. B60L 58/14

(52) U.S. Cl. CPC B60L 58/14; B60L 2240/28; B60L 2240/549; B60L 2250/20; B60L 2250/22; B60L 2260/26

(57) ABSTRACT

A battery control system of one aspect includes: a battery state detection unit that detects a state value of a battery; a control unit that controls power supply from the battery to a vehicle based on the state value; and a door opening/closing detection unit that detects opening and closing of a door of the vehicle. The control unit interrupts the power supply from the battery to the vehicle when the state value is equal to or lower than a first threshold value, and restarts the interrupted power supply when an open state of the door is detected.

### INCORPORATION BY REFERENCE

The present application claims priority under 35 U.S.C. § 119 to Japanese Patent Application No.2025-009775 filed on Jan. 23, 2025. The content of the application is incorporated herein by reference in its entirety.

### BACKGROUND OF THE INVENTION

### Field of the Invention

The present disclosure relates to a battery control system, a control method, and a recording medium.

### Description of the Related Art

In recent years, in order to ensure access to sustainable and advanced energy that is affordable and reliable for a large number of people, research and development have been conducted on a vehicle contributing to improvement in efficiency of energy.

Hitherto, a battery mounted on a vehicle is a lead-acid battery and is thus difficult to estimate the state of charge (SOC), and it has been difficult to avoid battery exhaustion. In view of the above, with the battery mounted on the vehicle being changed to an LIB (lithium-ion battery), it becomes possible to estimate the state of charge, and the battery exhaustion can be avoided by interrupting power supply from the battery when the state of charge is equal to or lower than a threshold value. U.S. Patent Application Publication No. 2014/0159670 discloses a conventional technology in which, in a power control apparatus for a vehicle battery, power from the battery is interrupted in accordance with a detection value of a current sensor, and is returned to a power supply state by manipulating a return switch.

However, in the above-mentioned conventional technology, it is required to manipulate the return switch for return to the power supply state from the battery, and there has been a problem in that it is inconvenient for the user.

The present invention has been made in view of the above-mentioned problem, and has an object to achieve battery control for a vehicle that is convenient for the user.

### SUMMARY OF THE INVENTION

One aspect for achieving the above-mentioned object resides in a battery control system including: a battery state detection unit that detects a state value of a battery; a control unit that controls power supply from the battery to the vehicle based on the state value; and a door opening/closing detection unit that detects opening and closing of a door of the vehicle, in which the control unit interrupts the power supply from the battery to the vehicle when the state value is equal to or lower than a first threshold value, and restarts the interrupted power supply when an open state of the door is detected.

According to the above-mentioned one aspect, it is possible to perform battery control for a vehicle that is convenient for the user.

### BRIEF DESCRIPTION OF THE DRAWINGS

FIG. 1 is a block diagram illustrating a configuration example of a vehicle control system according to one embodiment;

FIG. 2 is an explanatory view illustrating an example of area sections of a host vehicle to which the vehicle control system according to the one embodiment is mounted;

FIG. 3 is a flowchart illustrating an operation example of the vehicle control system according to the one embodiment;

FIG. 4 is a timing chart illustrating an example of power supply restart from a battery;

FIG. 5 is a timing chart illustrating an example of power supply interruption from the battery;

FIG. 6 is a flowchart illustrating an operation example of the vehicle control system according to the one embodiment;

FIG. 7 is a flowchart illustrating an operation example of the vehicle control system according to the one embodiment;

FIG. 8 is a flowchart illustrating an operation example of the vehicle control system according to the one embodiment;

FIG. 9 is a flowchart illustrating an operation example of the vehicle control system according to the one embodiment;

FIG. 10 is a flowchart illustrating an operation example of the vehicle control system according to the one embodiment;

FIG. 11 is a flowchart illustrating an operation example of the vehicle control system according to the one embodiment; and

FIG. 12 is a flowchart illustrating an operation example of the vehicle control system according to the one embodiment.

### DETAILED DESCRIPTION OF THE INVENTION

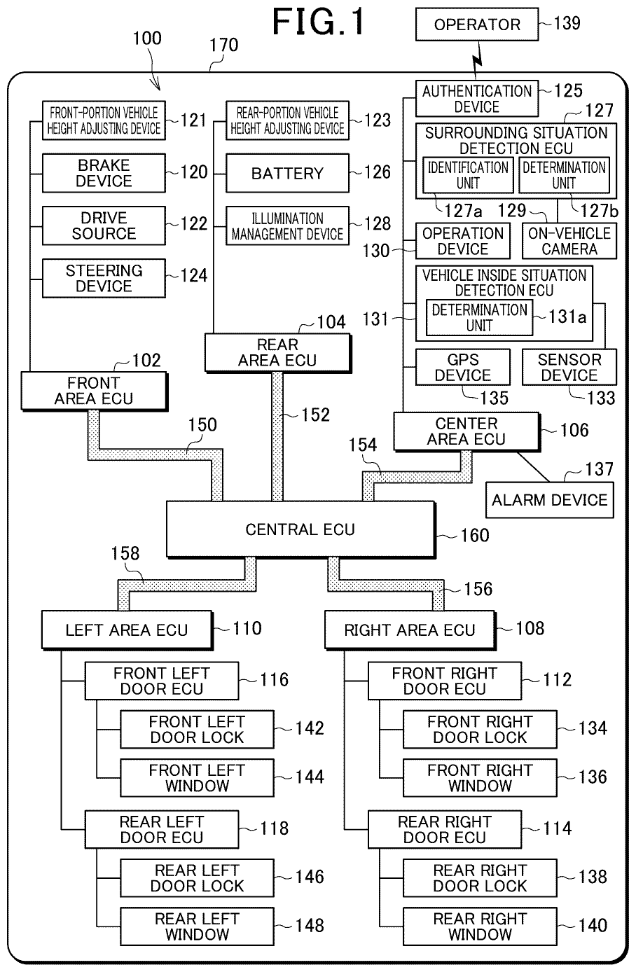

Hereinafter, a vehicle control system according to the present embodiment is described with reference to the drawings. FIG. 1 is a block diagram illustrating a configuration example of a vehicle control system according to one embodiment.

As illustrated in FIG. 1, a vehicle control system 100 is configured by connecting a plurality of control units that control an operation of a vehicle including a battery 126 so as to be communicable with each other. The vehicle control system 100 is an example of a battery control system. In the present embodiment, the above-mentioned control units are ECUs (Electronic Control Units) (computers).

Specifically, the vehicle control system 100 is mounted on a host vehicle 170, and includes a front area ECU 102, a rear area ECU 104, a center area ECU 106, a right area ECU 108, and a left area ECU 110. The front area ECU 102, the rear area ECU 104, the center area ECU 106, the right area ECU 108, and the left area ECU 110 are control devices that respectively control a plurality of control targets mounted on the host vehicle 170.

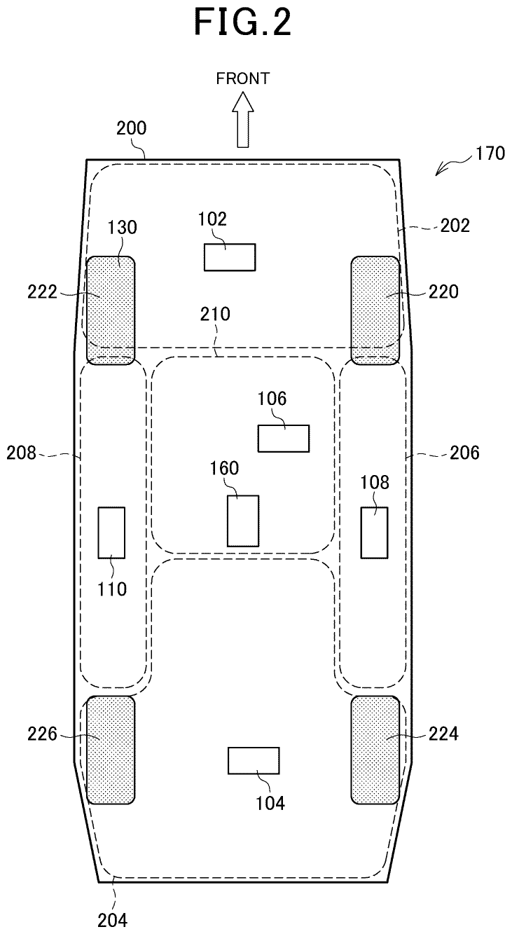

FIG. 2 is a view illustrating an example of area sections of a vehicle body 200 of the host vehicle 170. FIG. 2 illustrates the vehicle body 200 assuming a direction indicated by the white arrow in the illustration as front. As illustrated in FIG. 2, the vehicle body 200 is divided into, for example, a front area 202, a rear area 204, a right area 206, a left area 208, and a center area 210.

The front area 202 is a vehicle body region including portions of a front wheel 220 and a front wheel 222. The rear area 204 is a vehicle body region on the lower half of the illustration with respect to substantially the center of the vehicle body 200. The right area 206 is a vehicle body region sandwiched between the front wheel 220 and a rear wheel 224 on the right side of the illustration of the vehicle body 200. The left area 208 is a vehicle body region sandwiched between the front wheel 222 and a rear wheel 226 on the left side of the illustration. The center area 210 is a region at the vehicle body center surrounded by those areas.

The front area ECU 102, the rear area ECU 104, the center area ECU 106, the right area ECU 108, and the left area ECU 110 are each provided in each of the divided areas described above. That is, the front area ECU 102 is provided in the front area 202. The rear area ECU 104 is provided in the rear area 204. The center area ECU 106 is provided in the center area 210. The right area ECU 108 is provided in the right area 206. The left area ECU 110 is provided in the left area 208.

For example, the front area ECU 102 controls operations of a brake device 120 (computer), a front-portion vehicle height adjusting device 121, a drive source 122, and a steering device 124 (computer), which are control targets mounted in the front area 202 of the host vehicle 170. The front-portion vehicle height adjusting device 121 is an air suspension mechanism or the like provided on the front wheel 220 and the front wheel 222 in the front area 202 of the host vehicle 170. The drive source 122 is a motive power source of the host vehicle 170, and includes an internal combustion engine, a motor, a power generator, and the like.

The front area ECU 102 controls the operation of the drive source 122, and detects a state of the drive source 122 to notify each ECU such as a central ECU 160 of the detected state via a communication cable 150. It is to be noted that examples of the state of the drive source 122 to be detected by the front area ECU 102 include whether or not the drive source 122 is activated. That is, the front area ECU 102 is an example of a drive source state detection unit that detects a state of the drive source 122 of the host vehicle 170.

The rear area ECU 104 controls operations of a rear-portion vehicle height adjusting device 123, the battery 126 connected to auxiliary equipment, and an illumination management device 128 (computer) that manages on and off of a light such as a direction indicator lamp, a reversing lamp, a license plate lamp, a tail lamp, and the like, which are control targets mounted in the rear area 204. The rear-portion vehicle height adjusting device 123 is an air suspension mechanism or the like provided on the rear wheel 224 and the rear wheel 226 in the rear area 204 of the host vehicle 170.

The battery 126 is, for example, a low-voltage battery having a voltage value of about 12 [V], and supplies power to auxiliary equipment provided to the host vehicle (for example, each ECU and electric components connected to the ECU, such as an on-vehicle camera 129). The battery 126 is an LIB or the like as an example, and is a secondary battery that can detect a state value indicating the state of charge (SOC) by means of a current measurement method (coulomb counter method) or estimation based on the voltage value. The battery 126 is connected to a high-voltage power supply related to the drive source 122 and a high-voltage battery (not shown) or the like that supplies power to the drive source 122, via a DC-DC converter (not shown). The battery 126 is charged by converting the power supplied from the high-voltage power supply with the DC-DC converter. The state value indicating the state of charge (SOC) of the battery 126 is an index value indicating the state of the battery 126, and may be detected by a publicly-known method. For example, the state value may be detected based on any one of a charge ratio relative to full charge, a battery voltage, and an integrated value of current of the battery 126. In the present embodiment, the charge ratio is detected as the state value as an example. The rear area ECU 104 detects a voltage value of the battery 126 and a current amount or the like supplied to each unit by the battery 126, and detects a state value (as an example, a charge ratio) of the battery 126 by the current measurement method described above. That is, the rear area ECU 104 is an example of a battery state detection unit that detects a state value of the battery 126. For example, when the battery 126 includes an internal ECU that detects the state value of the battery 126 similarly to the above-mentioned rear area ECU, this internal ECU may be the battery state detection unit.

The battery 126 is charged by converting power generated by using the motive power of the drive source 122 or regenerative power at the time of deceleration of the host vehicle 170, which is stored in the high-voltage battery (not shown), into a low voltage via the DC-DC converter. Further, power supply or interruption of the power supply from the battery 126 to the auxiliary equipment is controlled by switch control of the rear area ECU 104 based on the state value of the battery 126.

For example, the rear area ECU 104 performs power supply from the battery 126 to the host vehicle 170 by closing the switch of the battery 126 when the state value of the battery 126 exceeds a predetermined threshold value. Further, the rear area ECU 104 interrupts the power supply from the battery 126 to the host vehicle 170 by opening the switch of the battery 126 when the state value of the battery 126 is equal to or lower than the predetermined threshold value. This makes it possible to suppress battery exhaustion in the vehicle control system 100. It is to be noted that details of the control of the rear area ECU 104 for suppressing the battery exhaustion are described later.

The center area ECU 106 controls operations of an authentication device 125 (computer), a surrounding situation detection ECU 127, an operation device 130, a vehicle inside situation detection ECU 131, a GPS device 135, and an alarm device 137, which are control targets mounted in the center area 210.

The authentication device 125 authenticates an operator 139 by communication (for example, near field communication) with the operator 139 such as a smart key and a smart phone associated with the host vehicle 170. The authentication device 125 is an example of an authentication unit.

The surrounding situation detection ECU 127 is connected to the on-vehicle camera 129 directed outside and inside of the vehicle, and detects a person present around and inside the host vehicle 170 based on an image taken by the on-vehicle camera 129. The surrounding situation detection ECU 127 is an example of a vehicle surrounding situation detection unit and a vehicle inside situation detection unit. Specifically, the surrounding situation detection ECU 127 includes an identification unit 127a and a determination unit 127b.

The identification unit 127a is a processing unit that identifies the person detected based on the image taken by the on-vehicle camera 129. Specifically, the identification unit 127a uses a publicly-known image recognition technology to compare an image region of the person detected by the image taken by the on-vehicle camera 129 with an image of a person stored in advance in a memory or the like, to thereby identify the detected person. In this case, the image of the person stored in advance in the memory or the like includes, in addition to an image of a user (for example, an owner of the host vehicle 170) that carries the operator 139 associated with the host vehicle 170, an image of a person taken at a driver's seat by the on-vehicle camera 129 that takes an image of the inside of the host vehicle 170, that is, an image of a person driving the host vehicle 170. Further, an image of a person stored in advance in a memory or the like includes an image of a person taken inside the vehicle by the on-vehicle camera 129 that takes an image of the inside the vehicle of the host vehicle 170, that is, an image of a person on board the host vehicle 170. Accordingly, the identification unit 127a can identify whether or not the detected person is a person having a history of driving the host vehicle 170. Further, the identification unit 127a can identify whether or not the detected person is a person having a history of being on board the host vehicle 170.

The determination unit 127b is a processing unit that determines whether or not an abnormality has occurred based on the identification result of the identification unit 127a. Specifically, when a target person other than the user carrying the operator 139 or a person on board the host vehicle 170 is detected based on the identification result of the identification unit 127a, the determination unit 127b determines whether or not an abnormality corresponding to an alarm target has occurred based on a threat level of the target person. When the determination unit 127b determines that an abnormality corresponding to an alarm target has occurred, the determination unit 127b outputs an abnormality signal to another control unit such as the center area ECU 106.

For example, the determination unit 127b obtains a time in which the target person is wandering around the host vehicle 170 based on a time in which the image region of the target person is detected from the taken image. Further, the determination unit 127b obtains a distance or the like of the target person approaching the vicinity of the driver's seat of the host vehicle 170 based on the position, the size, and the like of the image region of the target person in the taken image. The determination unit 127b uses the time, the distance, or the like obtained as described above as an index value indicating the threat level of the target person with respect to the host vehicle 170. When this threat level is higher than a predetermined threshold value, the determination unit 127b determines that the target person is causing an abnormality (for example, theft or damage) corresponding to an alarm target to the host vehicle 170.

The operation device 130 is operation equipment on which the user performs operation, such as an accelerator pedal, a brake pedal, a steering wheel, and a shift lever. The center area ECU 106 controls operations such as signal reception from those pieces of operation equipment.

The vehicle inside situation detection ECU 131 is connected to a sensor device 133, and detects the state of the host vehicle 170 based on a measurement result of the sensor device 133. The vehicle inside situation detection ECU 131 includes a determination unit 131a.

The sensor device 133 is, for example, an ultrasonic sensor that detects an object present around the host vehicle 170, a tilt sensor that detects the tilt of the host vehicle 170, or the like. As described above, the sensor device 133 may be any sensor as long as the sensor measures the state of the host vehicle 170 such as a situation around the host vehicle 170 and a tilt state of the host vehicle 170.

The determination unit 131a determines whether or not the host vehicle 170 is brought to an abnormality state corresponding to an alarm target based on the state of the host vehicle 170 acquired by the sensor device 133. For example, the determination unit 131a determines that the host vehicle 170 is brought to an abnormality state corresponding to an alarm target when a variation amount per unit time of the state of the host vehicle 170 (for example, a distance from an object present around the host vehicle 170 or the tilt of the host vehicle 170) becomes equal to or larger than a predetermined threshold value. When the determination unit 131a determines that the host vehicle 170 is brought to an abnormality state corresponding to an alarm target, the determination unit 131a transmits an abnormality signal to another control unit such as the center area ECU 106.

The GPS device 135 acquires a present position (vehicle position) of the host vehicle 170 based on a signal from a GPS (Global Positioning System) satellite. The GPS device 135 notifies another control unit such as the center area ECU 106 of the acquired vehicle position.

The alarm device 137 is a lighting device or the like that turns on a hazard lamp or a sound emitting device that emits a warning sound. The activation of the alarm device 137 such as the emission of the warning sound and the turning on of the hazard lamp is controlled by the center area ECU 106. It is to be noted that the alarm device 137 may be configured not only to issue an alarm by sound or light but also to issue an alarm to the operator 139 or the like via a communication network such as a wireless LAN.

The right area ECU 108 controls, via a front right door ECU 112 and a rear right door ECU 114 that respectively control operations of a front right door and a rear right door, a locking/unlocking operation of a front right door lock 134 mounted in the right area 206 and an opening/closing operation of a front right window 136, and a locking/unlocking operation of a rear right door lock 138 and an opening/closing operation of a rear right window 140. For example, the right area ECU 108 detects, when the front right door lock 134 or the rear right door lock 138 is unlocked, opening and closing of the front right door or the rear right door by an open/close switch that operates in accordance with the opening and closing of the front right door or the rear right door. That is, the right area ECU 108 is an example of a door opening/closing detection unit that detects opening and closing of a front right door or a rear right door in the host vehicle 170.

Further, the left area ECU 110 controls, via a front left door ECU 116 and a rear left door ECU 118 that respectively control operations of a front left door and a rear left door, a locking/unlocking operation of a front left door lock 142 mounted in the left area 208 and an opening/closing operation of a front left window 144, and a locking/unlocking operation of a rear left door lock 146 and an opening/closing operation of a rear left window 148. For example, the left area ECU 110 detects, when the front left door lock 142 or the rear left door lock 146 is unlocked, opening or closing of the front left door or the rear left door by an open/close switch that operates in accordance with the opening or closing of the front left door or the rear left door. That is, the left area ECU 110 is an example of a door opening/closing detection unit that detects opening or closing of a front left door or a rear left door in the host vehicle 170. It is to be noted that the above-mentioned opening/closing detection of the front right door, the rear right door, the front left door, or the rear left door is merely an example, and the opening or closing of the door may be detected by another switch or the like. For example, the opening or closing of the door may be detected by a lock switch that operates in accordance with unlocking of a mechanical key.

The vehicle control system 100 further includes the central ECU 160. The central ECU 160 is connected by communication cables 150, 152, 154, 156, and 158 such as CAN (Controller Area Network) buses to the respective area ECUs (the front area ECU 102, the rear area ECU 104, the center area ECU 106, the right area ECU 108, and the left area ECU 110) and devices connected to the respective area ECUs so as to be communicable with each other.

The central ECU 160 gives an operation instruction to the front area ECU 102, the rear area ECU 104, the center area ECU 106, the right area ECU 108, and the left area ECU 110 to cause, for example, a plurality of control targets to perform cooperative operations as targets, and an operation instruction based on a user operation input. The central ECU 160 is a control unit that is in a higher level than the front area ECU 102, the rear area ECU 104, the center area ECU 106, the right area ECU 108, and the left area ECU 110. The central ECU 160 manages a control operation for the control target to be performed by each area ECU and gives settings and instructions required for the control operation.

For example, the central ECU 160 calculates a steering angle, drive source output, drive force distribution, a brake operation amount, and the like for achieving a vehicle behavior corresponding to steering, an accelerator operation, or a pedal operation of the user, and transmits the calculated result to each area ECU. In each area ECU, an operation amount for a corresponding sub-system, actuator, or the like is calculated for drive so that the vehicle behavior desired by the user is achieved.

Further, the central ECU 160 transmits a control instruction signal for adjusting the state of the host vehicle 170 to each area ECU at a timing at which the user carrying the operator 139 gets on or off, a luggage is loaded, or the like or at a regular (for example, each period) adjustment timing of the host vehicle 170. In each area ECU, based on reception of the control instruction signal for adjusting the state of the host vehicle 170, the state of the host vehicle 170 is adjusted by operating its own equipment being the control target.

For example, the front area ECU 102 activates the front-portion vehicle height adjusting device 121 based on the reception of the control instruction signal for adjusting the state of the host vehicle 170 to perform vehicle height adjustment to bring the front portion of the host vehicle 170 to a predetermined vehicle height. Similarly, the rear area ECU 104 activates the rear-portion vehicle height adjusting device 123 based on the reception of the control instruction signal for adjusting the state of the host vehicle 170 to perform vehicle height adjustment to bring the rear portion of the host vehicle 170 to a predetermined vehicle height. It is to be noted that the adjustment of the state of the host vehicle 170 is not limited to the vehicle height adjustment of the host vehicle 170. For example, the adjustment of the state of the host vehicle 170 may be ventilation by opening an electric roof (not shown) under control of the center area ECU 106.

Further, when the central ECU 160 receives a lock operation or the like performed by the operator 139 associated with the authentication device 125, the central ECU 160 instructs each area ECU to start a security operation to activate a security function. In each area ECU, based on the instruction to start the security operation, a security operation of activating the alarm device 137 when an abnormality state corresponding to an alarm target is detected is started.

Specifically, the center area ECU 106 activates the alarm device 137 when receiving an abnormality signal corresponding to an abnormality state being an alarm target from the surrounding situation detection ECU 127 or the vehicle inside situation detection ECU 131. This causes the alarm device 137 to issue occurrence of an abnormality being an alarm target in the host vehicle 170 as an alarm.

Further, the central ECU 160 starts charging of the battery 126 via the DC-DC converter by turning on the high-voltage power supply. Further, operations for automatic driving and obstacle avoidance may be performed under the instruction of the central ECU 160.

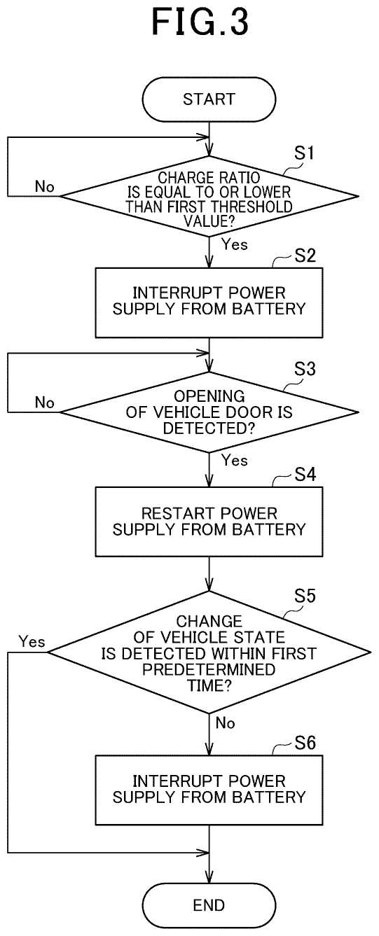

Here, the control of the power supply from the battery 126 to the host vehicle 170, which is performed by the rear area ECU 104, is described in detail with reference to FIG. 3 to FIG. 12.

FIG. 3 is a flowchart illustrating an operation example of the vehicle control system 100 according to one embodiment. It is to be noted that, at the time when processing in FIG. 3 is started, the power supply from the battery 126 to the host vehicle 170 is performed.

As illustrated in FIG. 3, when the processing is started, the rear area ECU 104 determines whether or not the state value of the battery 126 is equal to or lower than a first threshold value (S1).

Here, the first threshold value refers to a threshold value (for example, 30% or the like) having a sufficient margin with respect to battery exhaustion, and is set in advance in a memory of the rear area ECU 104 or the like.

The rear area ECU 104 stands by for processing when the state value of the battery 126 is not equal to or lower than the first threshold value (S1: No). The rear area ECU 104 interrupts the power supply from the battery 126 to the host vehicle 170 when the state value of the battery 126 is equal to or lower than the first threshold value (S1: Yes) (S2). That is, the rear area ECU 104 sets a safe mode in which the state value of the battery 126 is prevented from decreasing any more by interrupting the power supply from the battery 126.

Then, the rear area ECU 104 determines whether or not the opening of the door of the host vehicle 170 is detected based on the detection result of the right area ECU 108 or the left area ECU 110 (S3).

The rear area ECU 104 stands by for processing and continues the above-mentioned safe mode when the opening of the door is not detected (S3: No). When the opening of the door is detected (S3: Yes), the rear area ECU 104 restarts the power supply from the battery 126 to the host vehicle 170 (S4).

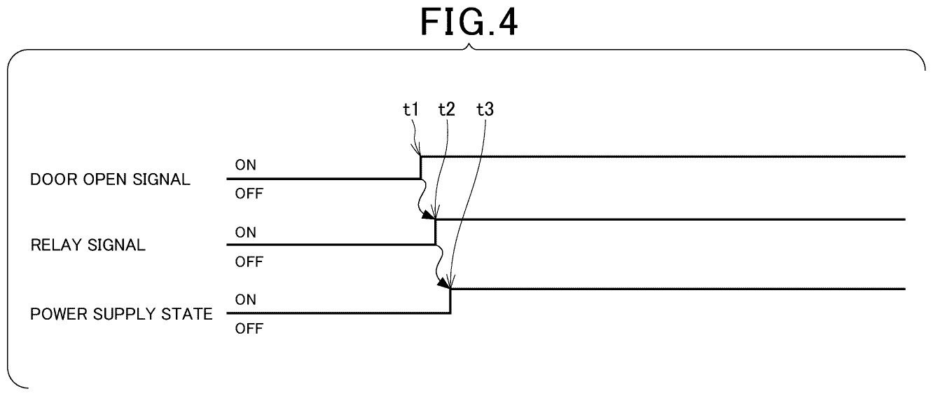

FIG. 4 is a timing chart illustrating an example of power supply restart from the battery 126. A door open signal of FIG. 4 is a signal of an open/close switch corresponding to the door lock (the front right door lock 134, the rear right door lock 138, the front left door lock 142, or the rear left door lock 146), which is directly connected via a harness or the like from the battery 126. A relay signal of FIG. 4 is a signal issued by a relay connected to the rear area ECU by performing switching based on the door open signal. For example, when the power supply from the battery 126 to the auxiliary equipment is interrupted, communication between the ECUs cannot be performed. Thus, in the present embodiment, earth fault of the battery 126 due to the opening of the door is detected by the open/close switch directly connected via the harness or the like from the battery 126 (t1), and a detection result of the opening of the door is transmitted through relay to the rear area ECU (t2). The rear area ECU 104 restarts (ON) the power supply of the battery 126 based on ON of this relay signal (t3).

It is to be noted that, when power supply is performed directly via the harness or the like from the battery 126 to the auxiliary equipment related to the door such as the right area ECU 108 or the left area ECU 110, the opening of the door of the host vehicle 170 may be detected based on the detection result of the right area ECU 108 or the left area ECU 110. For example, the right area ECU 108 or the left area ECU 110 notifies each ECU of the door open signal when the door (front right, rear right, front left, or rear left) of the host vehicle 170 is opened (t1). The rear area ECU 104 that has received the notification of the door open signal turns ON the relay signal corresponding to the opening of the door (t2). The rear area ECU 104 restarts (ON) the power supply of the battery 126 based on ON of this relay signal (t3).

Then, the ECU (not shown) provided in the battery 126 counts the time from the restart of the power supply, and determines whether or not the drive source 122 is turned on (activated) within a first predetermined time (S5). Alternatively, the ECU provided in the battery 126 may determine whether or not the drive source 122 is turned on (activated) by detecting whether or not the state value is recovered (raised) by the start of charge due to ON of the drive source 122. It is to be noted that the above-mentioned determination may be made in response to the reception of the notification of the front area ECU 102. Specifically, the rear area ECU 104 determines whether or not the drive source 122 is turned on (activated) within the first predetermined time and the change of the vehicle state is detected, based on the notification from the front area ECU 102 (S5).

Here, the first predetermined time refers to a time in which only a small power amount to be supplied by the battery 126 is required while power generation by the motive power of the drive source 122 is not performed, and is set in advance in the memory of the rear area ECU 104 or the like. For example, the first predetermined time is a time of about several minutes in which the power amount to be supplied by the battery 126 when the power generation by the motive power of the drive source 122 is not performed becomes a few percent when being converted into the state value.

When the drive source 122 is not turned on within the first predetermined time (S5: No), the rear area ECU 104 interrupts the power supply from the battery 126 (S6), and ends the processing. When the drive source 122 is turned on within the first predetermined time (S5: Yes), the rear area ECU 104 ends the processing in a state in which the power supply from the battery 126 to the host vehicle 170 is restarted.

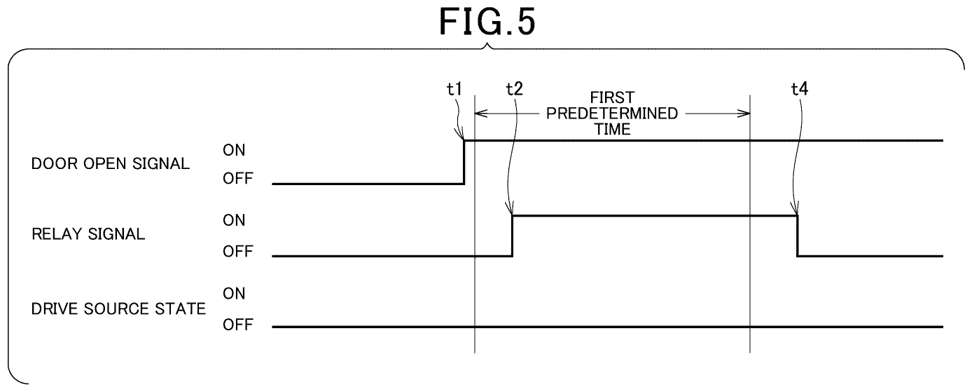

FIG. 5 is a timing chart illustrating an example of power supply interruption from the battery 126. As illustrated in FIG. 5, when the drive source 122 is not turned on within the first predetermined time, the rear area ECU 104 that has received the notification of the door open signal sets the relay signal to OFF (t4). The rear area ECU 104 interrupts (OFF) the power supply of the battery 126 based on the OFF of this relay signal.

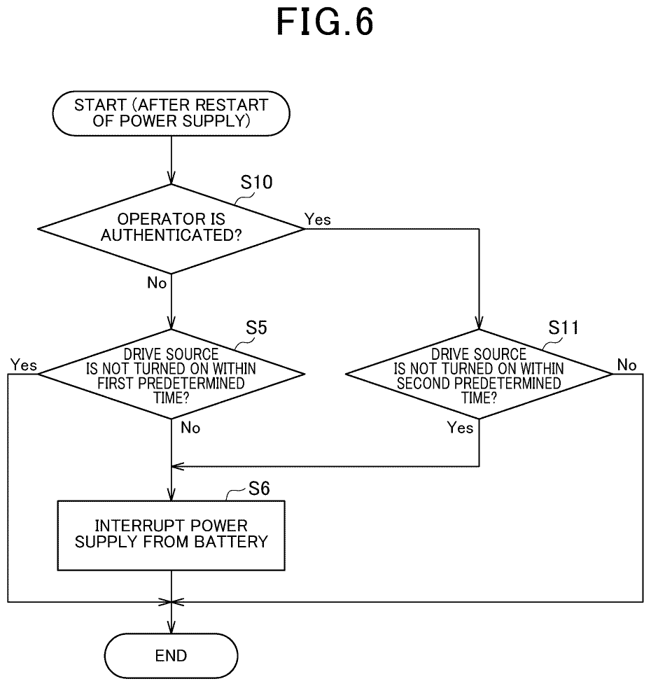

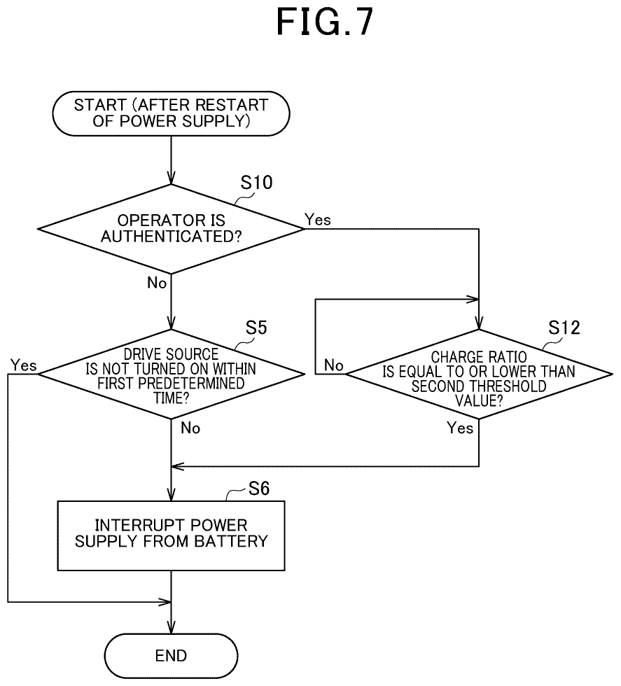

Next, description is given of a case in which the operator 139 is authenticated after the power supply from the battery 126 to the host vehicle 170 is restarted. FIG. 6 and FIG. 7 are flowcharts illustrating an operation example of the vehicle control system 100 according to the one embodiment, and illustrate an example of an operation after the power supply is restarted.

As illustrated in FIG. 6, after the power supply from the battery 126 to the host vehicle 170 is restarted, the authentication device 125 determines whether or not the operator 139 is authenticated (S10). When the operator 139 is not authenticated (S10: No), the rear area ECU 104 performs the processes of S5 and S6 described above.

When the operator 139 is authenticated (S10: Yes), the rear area ECU 104 determines whether or not the drive source 122 is turned on (activated) within a second predetermined time longer than the first predetermined time (S11).

Here, the second predetermined time refers to a time that is longer than the first predetermined time and has a larger power amount to be supplied by the battery 126 than the first predetermined time but requires a relatively small power amount, and is set in advance in the memory of the rear area ECU 104 or the like. For example, the second predetermined time is a time of about several tens of minutes in which the power amount to be supplied by the battery 126 when the power generation by the motive power of the drive source 122 is not performed becomes about 10% when being converted into the state value.

When the drive source 122 is not turned on within the second predetermined time (S11: Yes), the rear area ECU 104 interrupts the power supply from the battery 126 (S6), and ends the processing. When the drive source 122 is turned on within the second predetermined time (S11: No), the rear area ECU 104 ends the processing in a state in which the power supply from the battery 126 to the host vehicle 170 is restarted.

Further, as illustrated in FIG. 7, when the operator 139 is authenticated (S10: Yes), the rear area ECU 104 may determine whether or not the state value of the battery 126 is equal to or lower than a second threshold value (S12).

Here, the second threshold value refers to a threshold value (for example, 20%) that is lower than the above-mentioned first threshold value but does not reach the level at which the battery exhaustion occurs, and is set in advance in the memory of the rear area ECU 104 or the like.

When the state value of the battery 126 is not equal to or lower than the second threshold value (S12: No), the rear area ECU 104 stands by for processing. When the state value of the battery 126 is equal to or lower than the second threshold value (S12: Yes), the rear area ECU 104 interrupts the power supply from the battery 126 to the host vehicle 170 (S6).

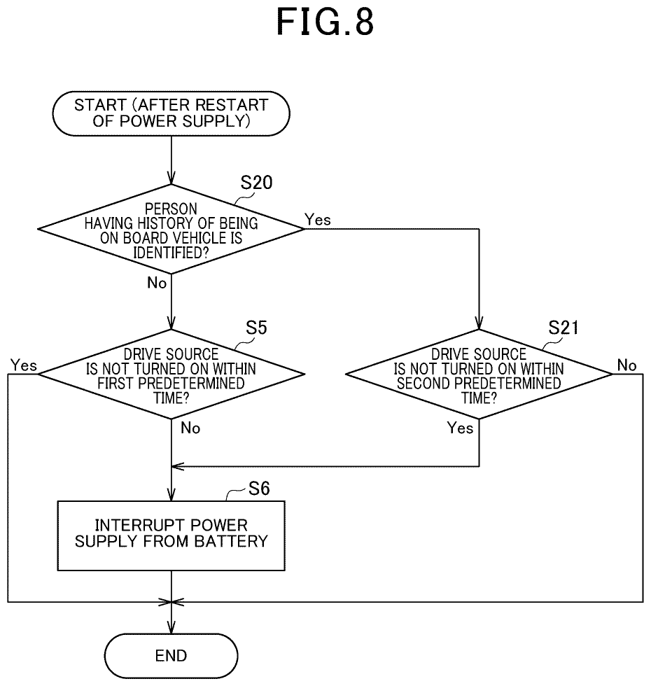

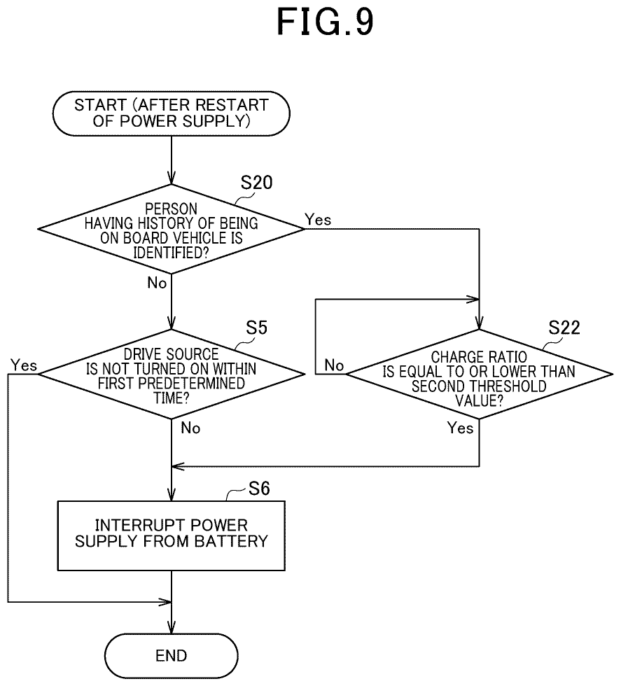

Next, description is given of a case in which, after the power supply from the battery 126 to the host vehicle 170 is restarted, a person present inside or outside of the host vehicle 170 is identified. FIG. 8 and FIG. 9 are flowcharts illustrating the operation example of the vehicle control system 100 according to the one embodiment, and illustrate an example of the operation after the power supply is restarted.

As illustrated in FIG. 8, after the power supply is restarted, the rear area ECU 104 determines whether or not the identification unit 127a identifies a person having a history of being on board the host vehicle 170 (S20). When no person having a history of being on board the host vehicle 170 is identified (S20: No), the rear area ECU 104 performs the processes of S5 and S6 described above.

When a person having a history of being on board the host vehicle 170 is identified (S20: Yes), the rear area ECU 104 determines whether or not the drive source 122 is turned on (activated) within a second predetermined time longer than the first predetermined time (S21).

When the drive source 122 is not turned on within the second predetermined time (S21: Yes), the rear area ECU 104 interrupts the power supply from the battery 126 (S6), and ends the processing. When the drive source 122 is turned on within the second predetermined time (S21: No), the rear area ECU 104 ends the processing in a state in which the power supply from the battery 126 to the host vehicle 170 is restarted.

Further, as illustrated in FIG. 9, when a person having a history of being on board the host vehicle 170 is identified (S20: Yes), the rear area ECU 104 may determine whether or not the state value of the battery 126 is equal to or lower than a second threshold value (S22).

When the state value of the battery 126 is not equal to or lower than the second threshold value (S22: No), the rear area ECU 104 stands by for processing. When the state value of the battery 126 is equal to or lower than the second threshold value (S22: Yes), the rear area ECU 104 interrupts the power supply from the battery 126 to the host vehicle 170 (S6).

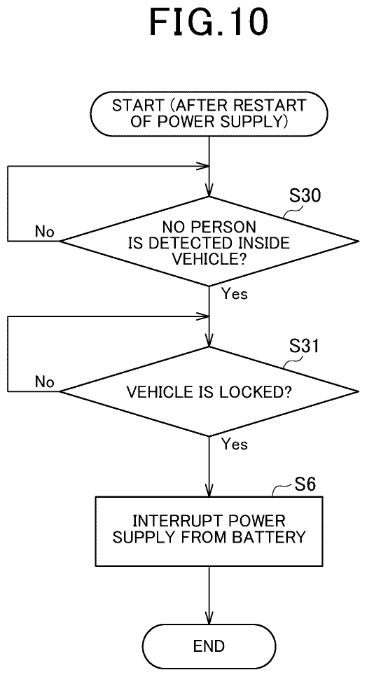

Next, description is given of a case in which, after the power supply from the battery 126 to the host vehicle 170 is restarted, the door of the host vehicle 170 is locked. FIG. 10 is a flowchart illustrating an operation example of the vehicle control system 100 according to the one embodiment, and illustrates an example of the operation after the power supply is restarted.

As illustrated in FIG. 10, after the power supply is restarted, the rear area ECU 104 determines whether or not the surrounding situation detection ECU 127 has detected a person inside the vehicle (S30). When a person is detected inside the vehicle (S30: No), the rear area ECU 104 stands by for processing.

When no person is detected inside the vehicle (S30: Yes), the rear area ECU 104 determines whether or not the door of the host vehicle 170 is locked (locking) based on the notification from the right area ECU 108 and the left area ECU 110 (S31). When the door of the host vehicle 170 is not locked (S31: No), the rear area ECU 104 stands by for the processing.

When the door of the host vehicle 170 is locked (S31: Yes), the rear area ECU 104 interrupts the power supply from the battery 126 to the host vehicle 170 (S6), and ends the processing.

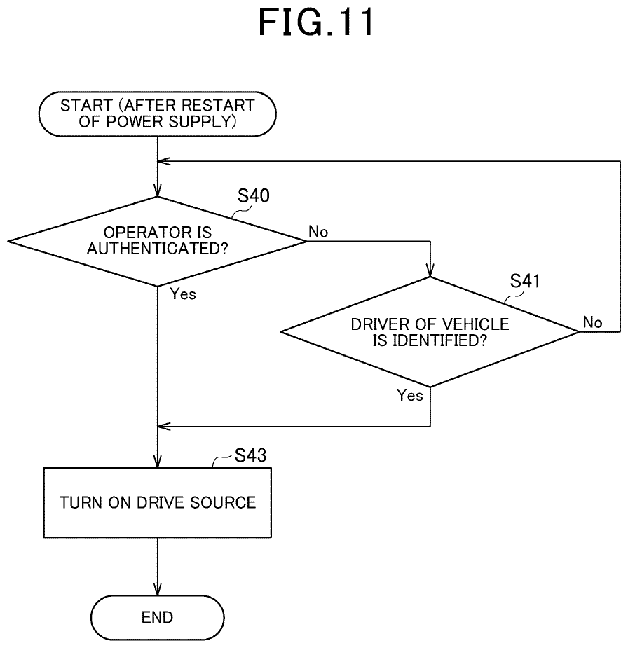

Description is given of a case in which, after the power supply from the battery 126 to the host vehicle 170 is restarted, the drive source 122 is turned on (activated) when the operator 139 is authenticated or the driver is identified. FIG. 11 is a flowchart illustrating an operation example of the vehicle control system 100 according to the one embodiment, and illustrates an example of the operation after the power supply is restarted.

As illustrated in FIG. 11, after the power supply is restarted, the rear area ECU 104 determines whether or not the authentication device 125 has authenticated the operator 139 (S40). When the operator 139 is not authenticated (S40: No), the rear area ECU 104 determines whether or not the identification unit 127a has identified the driver of the host vehicle 170 (S41). When the driver of the host vehicle 170 is not identified (S41: No), the rear area ECU 104 returns the process to S40.

When the operator 139 is authenticated (S40: Yes), or when the driver of the host vehicle 170 is identified (S41: Yes), the rear area ECU 104 turns on (activates) the drive source 122 (S43). As described above, the vehicle control system 100 may turn on (activate) the drive source 122 when the operator 139 is authenticated or the driver is identified after the power supply from the battery 126 is restarted.

Next, description is given of an operation in a case in which the state value of the battery 126 is equal to or lower than a third threshold value that is further lower than the second threshold value described above.

Here, the third threshold value is a threshold value that is lower than the above-mentioned second threshold value and close to the battery exhaustion (for example, 10%), and is set in advance in the memory of the rear area ECU 104 or the like.

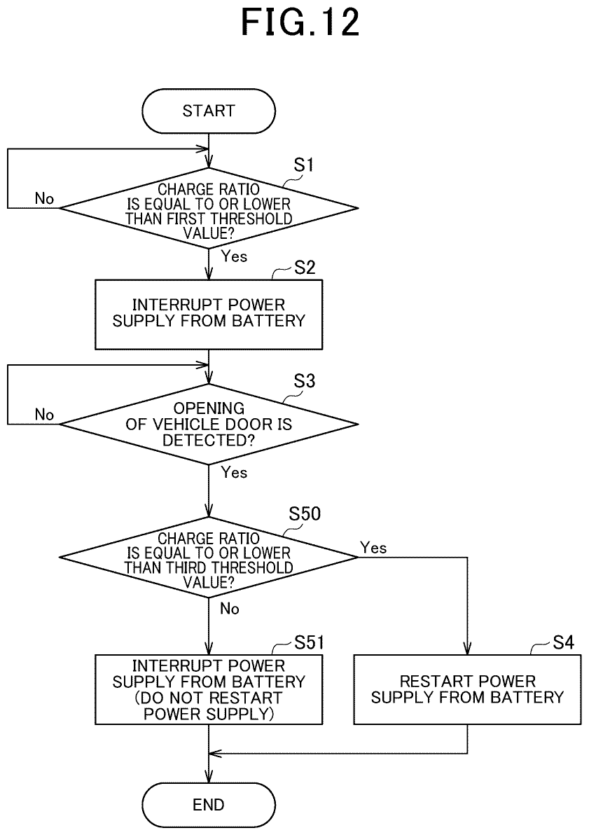

FIG. 12 is a flowchart illustrating an operation example of the vehicle control system 100 according to the one embodiment. As illustrated in FIG. 12, in the vehicle control system 100, processes up to S3 are performed similarly to the flowchart of FIG. 3.

Then, when the opening of the door is detected (S3: Yes), the rear area ECU 104 determines whether or not the state value of the battery 126 is equal to or lower than the third threshold value (S50).

When the state value of the battery 126 is not equal to or lower than the third threshold value (S50: No), the rear area ECU 104 restarts the power supply from the battery 126 to the host vehicle 170 (S4).

When the state value of the battery 126 is equal to or lower than the third threshold value (S50: Yes), the rear area ECU 104 maintains interruption of the power supply from the battery 126 without restarting the power supply from the battery 126 to the host vehicle 170 (S51). As described above, in the vehicle control system 100, when the state value of the battery 126 is equal to or lower than the third threshold value, the interruption of the power supply may be continued without restarting the power supply from the battery 126.

As described above, the rear area ECU 104 of the vehicle control system 100 detects the state value of the battery 126, and controls the power supply from the battery 126 to the host vehicle 170 based on the state value. The left area ECU 110 and the right area ECU 108 of the vehicle control system 100 detect the opening or closing the door (front right, rear right, front left, or rear left) of the host vehicle 170. The rear area ECU 104 interrupts the power supply from the battery 126 to the host vehicle 170 when the state value of the battery 126 is equal to or lower than the first threshold value, and restarts the interrupted power supply when the open state of the door is detected.

Accordingly, in the vehicle control system 100, when the state value of the battery 126 is equal to or lower than the first threshold value, the power supply from the battery 126 to the host vehicle 170 is interrupted, and the battery exhaustion can be avoided. Further, the interrupted power supply can be returned to the power supply state by opening the door of the host vehicle 170. Accordingly, the power supply state from the battery 126 can be returned with a simple operation of opening the door of the host vehicle 170, and hence the convenience of the user is improved. Further, opening the door is used as a switch for returning to the power supply state from the battery 126, and hence it is possible to reduce burdens in terms of cost and design for separately providing a dedicated return switch.

Further, the front area ECU 102 of the vehicle control system 100 detects the state of the drive source 122 of the host vehicle 170. After the power supply of the battery 126 is restarted, when the activation of the drive source 122 is not detected within the first predetermined time, the rear area ECU 104 interrupts the power supply.

Accordingly, in the vehicle control system 100, when the activation of the drive source 122 is not detected within the first predetermined time, the power supply from the battery 126 is interrupted, and it is thus possible to prevent battery exhaustion after the power supply is restarted.

Further, the vehicle control system 100 includes the authentication device 125 that authenticates the operator 139 associated with the host vehicle 170. After the power supply of the battery 126 is restarted, when the operator 139 is authenticated, and when the activation of the drive source 122 is not detected within the second predetermined time longer than the first predetermined time, the rear area ECU 104 interrupts the power supply.

Accordingly, in the vehicle control system 100, it is possible to prevent the battery exhaustion after the power supply is restarted while adapting to a use case such as work performed by the user having the operator 139 with the use of the power supplied from the battery 126.

Further, after the power supply of the battery 126 is restarted, when the operator 139 is authenticated, and when the state value of the battery 126 is equal to or lower than the second threshold value smaller than the first threshold value, the rear area ECU 104 interrupts the power supply.

Accordingly, in the vehicle control system 100, it is possible to more reliably prevent the battery exhaustion after the power supply is restarted while adapting to the use case of the user having the operator 139 described above.

Further, the vehicle control system 100 further includes the surrounding situation detection ECU 127 that detects a person present around the host vehicle 170, and the identification unit 127a that identifies the detected person. After the power supply of the battery 126 is restarted, when a person having a history of being on board the host vehicle 170 is identified, and when the activation of the drive source 122 is not detected within the second predetermined time longer than the first predetermined time, the rear area ECU 104 interrupts the power supply.

Accordingly, in the vehicle control system 100, it is possible to prevent the battery exhaustion after the power supply is restarted while adapting to a use case such as work performed by the user having a history of being on board the host vehicle 170 with the use of the power supplied from the battery 126.

Further, after the power supply of the battery 126 is restarted, when a person having a history of being on board the host vehicle 170 is identified, and when the state value of the battery 126 is equal to or lower than the second threshold value smaller than the first threshold value, the rear area ECU 104 interrupts the power supply.

Accordingly, in the vehicle control system 100, it is possible to more reliably prevent the battery exhaustion after the power supply is restarted while adapting to the use case of the user having a history of being on board the host vehicle 170 described above.

Further, the vehicle control system 100 includes the surrounding situation detection ECU 127 that detects a person present inside of the host vehicle 170. After the power supply of the battery 126 is restarted, when no person is detected inside of the host vehicle 170, the rear area ECU 104 interrupts the power supply after the door is locked.

Accordingly, in the vehicle control system 100, when, after the power supply from the battery 126 is restarted by opening the door, the power supply is interrupted, it is possible to prevent leaving or trapping of a person inside the vehicle and to improve anti-theft performance.

Further, after the power supply of the battery 126 is restarted, when the operator 139 is authenticated or a person driving the host vehicle 170 is identified, the rear area ECU 104 activates the drive source 122 of the host vehicle 170.

Accordingly, in the vehicle control system 100, as for the user having the operator 139 or the user driving the host vehicle 170, the charging to the battery 126 is allowed without performing an operation of activating the drive source 122 in order to charge the battery 126, and hence the convenience is improved.

Further, when the open state of the door of the host vehicle 170 is detected and when the state value of the battery 126 is equal to or lower than the third threshold value smaller than the first threshold value, the rear area ECU 104 continues the interruption of the power supply.

Accordingly, in the vehicle control system 100, even when the door of the host vehicle 170 is opened, when the state value of the battery 126 is equal to or lower than the third threshold value and an excessive load is applied to the battery 126 when the power supply is restarted, the interruption of the power supply can be continued. Accordingly, in the vehicle control system 100, it is possible to suppress application of an excessive load to the battery 126 and to suppress deterioration of the battery 126.

It is to be noted that the above-mentioned embodiment is merely an example of the art in the present disclosure, and hence it is possible to make various modifications, replacements, additions, omissions, and the like in the scope of claims or in an equivalent scope thereof.

Further, the configurations of the units of the vehicle control system 100 illustrated in FIG. 1 are merely examples, and specific embodiments are not particularly limited. That is, it is not always required to mount hardware individually corresponding to each unit, and, as a matter of course, the functions of the units may be implemented by executing a program by one processor. Further, some functions to be implemented by software in the above-mentioned embodiment may be hardware, or some functions to be implemented by hardware may be software.

Further, step units of the operation in the ECU such as the central ECU 160, the center area ECU 106, the rear area ECU 104, or the like of FIG. 1 are divided in accordance with main process contents, and the present disclosure is not limited by the way to divide the process units or the names. The step units may be divided into a larger number of step units in accordance with the process contents. Further, one step unit may be further divided to include still more processes. Further, the order of steps may be switched as appropriate without departing from the spirit of the present disclosure.

Further, when the control method using a computer such as the central ECU 160, the center area ECU 106, the rear area ECU 104, and the like of the vehicle control system 100 described above is achieved through use of a processor, a program to be executed by the processor can be configured in a form of a recording medium or a transmission medium for transmitting the program. That is, the above-mentioned program can be implemented in a state in which the program is recorded in a portable information recording medium. Examples of the information recording medium include a magnetic recording medium such as a hard disk, an optical recording medium such as a CD, and a semiconductor storage device such as a USB (Universal Serial Bus) memory or an SSD (Solid State Drive), but other recording media can also be used.

### Configurations Supported by Above-Mentioned Embodiment

The above-mentioned embodiment is supported by the following configurations.

(Configuration 1) A battery control system including: a battery state detection unit that detects a state value of a battery; a control unit that controls power supply from the battery to a vehicle based on the state value; and a door opening/closing detection unit that detects opening and closing of a door of the vehicle, in which the control unit interrupts the power supply from the battery to the vehicle when the state value is equal to or lower than a first threshold value, and restarts the interrupted power supply when an open state of the door is detected.

With the battery control system of configuration 1, it is possible to avoid battery exhaustion and to return to the power supply state from the battery by opening the door without performing the operation of a return switch. That is, the power supply state from the battery can be returned with a simple operation of opening the door, and hence the convenience of the user is improved. Further, it is possible to reduce burdens in terms of cost and design for providing the return switch.

(Configuration 2) The battery control system according to configuration 1, in which, after the power supply is restarted, when the state value is not increased within a first predetermined time, the control unit interrupts the power supply.

With the battery control system of configuration 2, when the state value is not increased within the first predetermined time, with the power supply from the battery being interrupted, it is possible to prevent battery exhaustion after the power supply is restarted.

(Configuration 3) The battery control system according to configuration 1, further including a drive source state detection unit that detects a state of a drive source of the vehicle, in which, after the power supply is restarted, when activation of the drive source is not detected within a first predetermined time, the control unit interrupts the power supply.

With the battery control system of configuration 3, when the activation of the drive source is not detected within the first predetermined time, with the power supply from the battery being interrupted, it is possible to prevent battery exhaustion after the power supply is restarted.

(Configuration 4) The battery control system according to configuration 3, further including an authentication unit that authenticates an operator associated with the vehicle, in which, after the power supply is restarted, when the operator is authenticated, and when the activation of the drive source is not detected within a second predetermined time longer than the first predetermined time, the control unit interrupts the power supply.

With the battery control system of configuration 4, it is possible to prevent the battery exhaustion after the power supply is restarted while adapting to the use case such as work performed by the user having the operator with the use of the power supplied from the battery.

(Configuration 5) The battery control system according to any one of configurations 1 to 3, further including an authentication unit that authenticates an operator associated with the vehicle, in which, after the power supply is restarted, when the operator is authenticated, and when the state value is equal to or lower than a second threshold value smaller than the first threshold value, the control unit interrupts the power supply.

With the battery control system of configuration 5, it is possible to more reliably prevent the battery exhaustion after the power supply is restarted while adapting to the use case such as work performed by the user having the operator with the use of the power supplied from the battery.

(Configuration 6) The battery control system according to any one of configurations 1 to 5, further including: a vehicle surrounding situation detection unit that detects a person present around the vehicle; and an identification unit that identifies the detected person, in which, after the power supply is restarted, when a person having a history of being on board the vehicle is identified, and when activation of the drive source is not detected within a second predetermined time longer than the first predetermined time, the control unit interrupts the power supply.

With the battery control system of configuration 6, it is possible to prevent the battery exhaustion after the power supply is restarted while adapting to the use case such as work performed by the user having a history of being on board the vehicle with the use of the power supplied from the battery.

(Configuration 7) The battery control system according to any one of configurations 1 to 5, further including: a vehicle surrounding situation detection unit that detects a person present around the vehicle; and an identification unit that identifies the detected person, in which, after the power supply is restarted, when a person having a history of being on board the vehicle is identified, and when the state value is equal to or lower than a second threshold value smaller than the first threshold value, the control unit interrupts the power supply.

With the battery control system of configuration 7, it is possible to more reliably prevent the battery exhaustion after the power supply is restarted while adapting to the use case such as work performed by the user having a history of being on board the vehicle with the use of the power supplied from the battery.

(Configuration 8) The battery control system according to any one of configurations 1 to 7, further including a vehicle inside situation detection unit that detects a person present inside of the vehicle, in which, after the power supply is restarted, when no person is detected inside of the vehicle, the control unit interrupts the power supply after the door is locked.

With the battery control system of configuration 8, when, after the power supply from the battery is restarted by opening the door, the power supply is interrupted, it is possible to prevent leaving or trapping of a person inside the vehicle and to improve anti-theft performance.

(Configuration 9) The battery control system according to configuration 1, further including: an authentication unit that authenticates an operator associated with the vehicle; a vehicle surrounding situation detection unit that detects a person present around the vehicle; and an identification unit that identifies the detected person, in which, after the power supply is restarted, when the operator is authenticated, or when a person driving the vehicle is identified, the control unit activates a drive source of the vehicle.

With the battery control system of configuration 9, as for the user having the operator or the user driving the vehicle, the charging to the battery is allowed without performing an operation of activating the drive source in order to charge the battery, and hence the convenience is improved.

(Configuration 10) The battery control system according to any one of configurations 1 to 9, in which, when the open state of the door is detected and when the state value is equal to or lower than a third threshold value smaller than the first threshold value, the control unit continues interruption of the power supply.

With the battery control system of configuration 10, even when the door is opened, when the state value of the battery is low and an excessive load is applied to the battery when the power supply is restarted, the interruption of the power supply can be continued. Accordingly, it is possible to suppress application of an excessive load to the battery and to suppress deterioration of the battery.

(Configuration 11) A control method for causing a computer to execute processing of: interrupting, when a state value of a battery that performs power supply to a vehicle is equal to or lower than a first threshold value, the power supply from the battery to the vehicle; and restarting the interrupted power supply when a door opening/closing detection unit that detects opening and closing of a door of the vehicle detects an open state of the door.

With the control method of configuration 11, effects equivalent to those of configuration 1 described above are produced.

(Configuration 12) A non-transitory computer readable recording medium recording a program for causing a computer to execute processing of: interrupting, when a state value of a battery that performs power supply to a vehicle is equal to or lower than a first threshold value, the power supply from the battery to the vehicle; and restarting the interrupted power supply when a door opening/closing detection unit that detects opening and closing of a door of the vehicle detects an open state of the door.

With the recording medium of configuration 12, effects equivalent to those of configuration 1 described above are produced.

### REFERENCE SIGNS LIST

100 . . . vehicle control system, 102 . . . front area ECU, 104 . . . rear area ECU, 106 . . . center area ECU, 108 . . . right area ECU, 110 . . . left area ECU, 112 . . . front right door ECU, 114 . . . rear right door ECU, 116 . . . front left door ECU, 118 . . . rear left door ECU, 120 . . . brake device, 121 . . . front-portion vehicle height adjusting device, 122 . . . drive source, 123 . . . rear-portion vehicle height adjusting device, 124 . . . steering device, 125 . . . authentication device, 126 . . . battery, 127 . . . surrounding situation detection ECU, 127a . . . identification unit, 127b . . . determination unit, 128 . . . illumination management device, 129 . . . on-vehicle camera, 130 . . . operation device, 131 . . . vehicle inside situation detection ECU, 131a . . . determination unit, 133 . . . sensor device, 134 . . . front right door lock, 135 . . . GPS device, 136 . . . front right window, 137 . . . alarm device, 138 . . . rear right door lock, 139 . . . operator, 140 . . . rear right window, 142 . . . front left door lock, 144 . . . front left window, 146 . . . rear left door lock, 148 . . . rear left window, 150 . . . communication cable, 152 . . . communication cable, 154 . . . communication cable, 156 . . . communication cable, 158 . . . communication cable, 160 . . . central ECU, 170 . . . host vehicle, 200 . . . vehicle body, 202 . . . front area, 204 . . . rear area, 206 . . . right area, 208 . . . left area, 210 . . . center area, 220 . . . front wheel, 222 . . . front wheel, 224 . . . rear wheel, 226 . . . rear wheel.

1. A battery control system comprising:
a battery state detection unit that detects a state value of a battery;
a control unit that controls power supply from the battery to a vehicle based on the state value; and
a door opening/closing detection unit that detects opening and closing of a door of the vehicle,
wherein the control unit interrupts the power supply from the battery to the vehicle when the state value is equal to or lower than a first threshold value, and restarts the interrupted power supply when an open state of the door is detected.

2. The battery control system according to claim 1, wherein, after the power supply is restarted, when the state value is not increased within a first predetermined time, the control unit interrupts the power supply.

3. The battery control system according to claim 1, further comprising a drive source state detection unit that detects a state of a drive source of the vehicle,
wherein, after the power supply is restarted, when activation of the drive source is not detected within a first predetermined time, the control unit interrupts the power supply.

4. The battery control system according to claim 3, further comprising an authentication unit that authenticates an operator associated with the vehicle,
wherein, after the power supply is restarted, when the operator is authenticated, and when the activation of the drive source is not detected within a second predetermined time longer than the first predetermined time, the control unit interrupts the power supply.

5. The battery control system according to claim 3, further comprising an authentication unit that authenticates an operator associated with the vehicle,
wherein, after the power supply is restarted, when the operator is authenticated, and when the state value is equal to or lower than a second threshold value smaller than the first threshold value, the control unit interrupts the power supply.

6. The battery control system according to claim 3, further comprising:
a vehicle surrounding situation detection unit that detects a person present around the vehicle; and
an identification unit that identifies the detected person,
wherein, after the power supply is restarted, when a person having a history of being on board the vehicle is identified, and when activation of the drive source is not detected within a second predetermined time longer than the first predetermined time, the control unit interrupts the power supply.

7. The battery control system according to claim 1, further comprising:
a vehicle surrounding situation detection unit that detects a person present around the vehicle; and
an identification unit that identifies the detected person,
wherein, after the power supply is restarted, when a person having a history of being on board the vehicle is identified, and when the state value is equal to or lower than a second threshold value smaller than the first threshold value, the control unit interrupts the power supply.

8. The battery control system according to claim 1, further comprising a vehicle inside situation detection unit that detects a person present inside of the vehicle,
wherein, after the power supply is restarted, when no person is detected inside of the vehicle, the control unit interrupts the power supply after the door is locked.

9. The battery control system according to claim 1, further comprising:
an authentication unit that authenticates an operator associated with the vehicle;
a vehicle surrounding situation detection unit that detects a person present around the vehicle; and
an identification unit that identifies the detected person,
wherein, after the power supply is restarted, when the operator is authenticated, or when a person driving the vehicle is identified, the control unit activates a drive source of the vehicle.

10. The battery control system according to claim 1, wherein, when the open state of the door is detected and when the state value is equal to or lower than a third threshold value smaller than the first threshold value, the control unit continues interruption of the power supply.

11. A control method for causing a computer to execute processing of:
interrupting, when a state value of a battery that performs power supply to a vehicle is equal to or lower than a first threshold value, the power supply from the battery to the vehicle; and
restarting the interrupted power supply when a door opening/closing detection unit that detects opening and closing of a door of the vehicle detects an open state of the door.

12. A non-transitory computer readable recording medium recording a program for causing a computer to execute processing of:
interrupting, when a state value of a battery that performs power supply to a vehicle is equal to or lower than a first threshold value, the power supply from the battery to the vehicle; and
restarting the interrupted power supply when a door opening/closing detection unit that detects opening and closing of a door of the vehicle detects an open state of the door.
